(19) United States
(12) Patent Application Publication
(10) Pub. No.: US 2022/0019011 A1
(43) Pub. Date: Jan. 20, 2022

(54) AN ENCLOSURE

(71) Applicant: UNIVERSITY OF BATH, Bath (GB)

(72) Inventors: Ventsislav VALEV, Bath (GB); Peter MOSLEY, Bath (GB); William WADSWORTH, Bath (GB); Dimitar SLAVOV, Plovdiv (BG); Kristina RUSIMOVA, Bath (GB)

(21) Appl. No.: 17/293,898

(22) PCT Filed: Nov. 12, 2019
(86) PCT No.: PCT/GB2019/053197

§ 371 Date: May 13, 2021

(30) Foreign Application Priority Data
Nov. 13, 2018 (GB) 1818455.6

(51) Int. Cl. F21V 8/00; G04F 5/14; G21K 1/00; G01R 33/26

(52) U.S. Cl. CPC G02B 6/0003; G01R 33/26; G21K 1/006; G04F 5/14

(57) ABSTRACT

An alkali metal vapor enclosure comprising: an internal surface comprising nanostructures; a transmissive portion to enable the internal surface to be illuminated; wherein the enclosure contains atoms of an alkali metal which are in a vapor state and/or adsorbed onto the internal surface; and wherein illumination of the internal surface via the transmissive portion with light having a frequency to cause a temperature rise in the nanostructures by exciting an enhanced optical extinction mechanism in the nanostructures, causes an increase in the density of the alkali metal vapor.

### BACKGROUND

Atomic vapors, for example alkali metal vapors, are used in many quantum optical applications, as the arrangement of energy levels in alkali metal atoms such as Rubidium and Caesium make them useful as frequency references and in studies of light-matter interaction. For example, alkali metal vapors are used in applications such as atomic clocks, high sensitivity magnetometers, atom cooling, precision spectroscopy, frequency stabilization and quantum interferometers. In such applications, the atomic vapor is often held in an enclosure such as a vacuum cell.

In enclosures for holding alkali metal vapors, the atoms of the alkali metal vapor tend to adsorb onto the internal walls of the cell, which reduces the density of the vapor and limits its optical depth. Additionally, the alkali metal vapor can react chemically with the enclosure material. To prevent such chemical reactions, various coatings are applied to the inner surface of the enclosure. Some of these coatings have “antirelaxation properties”, i.e. the alkali metal atoms can bounce very quickly off them (short collisions/dwell time), which preserves the quantum states of the atoms and increases the usefulness of the vapor for its applications.

### SUMMARY

According to a first aspect of the disclosure there is provided an alkali metal vapor enclosure comprising: an internal surface comprising nanostructures; and a transmissive portion to enable the internal surface to be illuminated; wherein the enclosure contains atoms of an alkali metal which are in a vapor state and/or adsorbed onto the internal surface; and arranged such that illumination of the internal surface via the transmissive portion with light having a frequency to cause a temperature rise in the nanostructures by exciting an enhanced optical extinction mechanism causes an increase in the density of the alkali metal vapor.

The first aspect of the disclosure enables control of adsorption and desorption of alkali metal vapor atoms from an internal surface of an alkali metal vapor enclosure by selectively exciting an enhanced optical extinction mechanism in the nanostructures, such that the nanostructures heat up, to cause local heating of the internal surface of the enclosure, thereby enabling control of the alkali metal vapor density in the enclosure. Such nanostructures will also cool down quickly, causing the alkali metal vapor density in the enclosure to rapidly decrease. The thermal response of the nanostructures is fast due to their small size. I.e. the nanostructure can heat up and cool down quickly. Therefore, this enables controlling (increasing and decreasing) the vapor density with fast reaction times

Nanostructures may have at least one dimension or feature sized between 1 and 100 nm.

The enhanced optical extinction mechanism may be a resonant absorption in the nanostructures. For example, the light may have a frequency to excite a surface plasmon resonance, an interband transition or an intraband transition in the nanostructures.

The internal surface may comprise nanostructures covered by a polymer layer.

The polymer layer may help to attach the nanostructures to the enclosure walls in some embodiments.

The polymer layer may help to prevent chemical reactions between alkali metal atoms and the nanostructures and between alkali metal atoms and the enclosure material. The polymer layer may also present antirelaxation properties, i.e. to help preserve the quantum states of the atoms upon collision with the walls.

The internal surface may comprise an antirelaxation coating. An antirelaxation coating provides antirelaxation properties that preserve the quantum states of atoms upon collision with the internal surface. The antirelaxation coating can be provided by the polymer layer, or another material having antirelaxation properties suitable to preserve the quantum states of atoms upon collision.

The polymer layer may comprise polydimethylsiloxane (PDMS), which is a polymer used for its antirelaxation properties.

The nanostructures may comprise nanoparticles, which exhibit fast thermal responses due to their small dimensions. The nanoparticles may comprise metal nanoparticles. Metal nanoparticles are readily available and exhibit strong enhanced optical extinction properties. In some examples, the nanoparticles may comprise gold nanoparticles. Gold nanoparticles have a surface plasmon resonance (SPR) and interband transitions that can be excited by light in the visible range, are relatively stable and unreactive and can be produced consistently with control over their sizes/shapes, which enables their SPR frequency to be tailored.

The enclosure may comprise a vacuum cell, which may comprise, at least in part, a glass or quartz transmissive portion, wherein the rest of the enclosure may be formed of a different material. Such materials are suitable for holding an alkali metal vapor in near vacuum conditions whilst being transmissive to light in the frequency range of interest (e.g. the visible range.)

The enclosure may be a hollow-core optical fiber. Using a hollow core optical fibre as the alkali metal vapor enclosure may be useful for applications requiring extremely low light levels, long interaction lengths, or compact architectures including mediating interactions between photons to enact quantum gate operations, quantum memories, or portable atomic clocks.

The nanostructures may be capped with an antirelaxation material. In some examples, the nanoparticles may be capped with octadecylamine (ODA). Capping the nanoparticles with ODA improves their chemical stability, prevents them from aggregating and enables them to be attached stably to the internal surface of the enclosure. ODA also presents very good antirelaxation properties.

The frequency of the nanostructure enhanced extinction mechanism may be a frequency that is excited by light in the ultraviolet, or visible, or the near infra-red part of the electromagnetic spectrum. In some examples, the frequency of the light may be in the visible range of the electromagnetic spectrum. For example, the frequency of the excitation light may be between 430 and 770 THz (corresponding to wavelengths of −0.389 nm and −0.697 nm).

Nanostructures which have an enhanced optical extinction which is excited at a frequency that matches a visible light frequency can be excited by light in the visible range, which is transmitted through standard materials used for alkali metal vapor enclosures, such as glass and quartz.

According to a second aspect of the disclosure there is provided a method of controlling an alkali metal vapor density comprising: illuminating an internal surface of an alkali metal vapor enclosure, wherein the internal surface comprises nanostructures, with light from a first light source, having a frequency to cause a temperature rise in the nanostructures by exciting an enhanced optical extinction mechanism in the nanostructures, which then causes heating in the nanoparticles and leads to a rise in the density of the alkali metal vapor.

The method may comprise selectively illuminating the alkali metal vapor via the transmissive portion with light from a second light source, wherein the light from the second light source is to interact with the alkali metal vapor.

Therefore, the method may comprise controlling the alkali metal vapor density so that it reaches a particular level and then illuminating the alkali metal vapor with light to produce quantum optical effects caused by interaction of the light with the alkali metal vapor, which has applications in, for example, atomic clocks, magnetometers, photonic sensors, quantum switches, quantum gates, quantum memory, atom traps, quantum interferometers, laser frequency stabilizers, quantum limited amplifiers and quantum delay lines.

The method may comprise removing the light from the first light source from the internal surface to cause a decrease in the density of the alkali metal vapor.

This enables the density of the alkali metal vapor to be decreased as well as increased, thereby giving a greater degree of control over the vapor density.

According to a third aspect of the disclosure there is provided a method of producing an alkali metal vapor enclosure comprising: forming an enclosure having a transmissive portion; coating an internal surface of the enclosure with nanostructures; evacuating air from the enclosure; introducing an alkali metal vapor into the enclosure; and sealing the enclosure.

In other words, this method is a method of producing an alkali metal vapor enclosure according to the first aspect of the disclosure.

A fourth aspect of the disclosure comprises use of an alkali metal vapour cell according to the first aspect of the disclosure in an atomic clock, a magnetometer, an atom trap, or a laser frequency stabilizer.

Further aspects may comprise any of: an atomic clock, a magnetometer, a photonic sensor, a quantum switch, a quantum logic gate, a quantum memory based on quantum logic gates, an atom trap (e.g. for quantum information experiments that require long coherence times), a quantum interferometer, a laser frequency stabilizer (e.g. where the light scattered from atomic vapor is measured across hyper-fine atomic level transitions and is fed back to the laser diode controller), quantum limited amplifiers or a quantum delay line comprising an alkali metal vapor enclosure according to the first aspect of the disclosure.

### BRIEF DESCRIPTION OF THE DRAWINGS

FIG. 1 shows a schematic representation of an example alkali metal vapor enclosure.

FIG. 2 shows a schematic representation of an inner surface of an example alkali metal vapor enclosure.

FIG. 3 shows a schematic representation of another example of an inner surface of alkali metal vapor enclosure.

FIG. 4 shows a schematic representation of another example of an alkali metal vapor enclosure.

FIG. 5 shows a flow diagram of an example method of controlling vapor density in an alkali metal vapor enclosure.

FIG. 6 shows a flow diagram of another example method of controlling vapor density in an alkali metal vapor enclosure.

FIG. 7 shows a flow diagram of an example method of producing an alkali metal vapor enclosure.

### DETAILED DESCRIPTION

Alkali metal vapors in confined geometries can be used in applications in quantum optical technology, both as isolated atoms and as coherent ensembles of atoms. Alkali metal atoms can be viewed as one electron systems, due to the presence of a single electron in the outer shell. The resulting sharp resonances find applications in atom cooling, precision spectroscopy and in the frequency stabilization of laser on atomic transitions. Associated A-type systems serve as a basis for atomic clocks and magnetometry (e.g. for cardiograms and encephalograms), using coherent population trapping (CPT). The CPT effect also leads to electromagnetically induced transparency (EIT). In turn, the sharp variation of refractive index in the narrow frequency region of EIT can slow down light pulses, effectively trapping them in a vapor enclosure. Mapping optical quantum states into coherent behaviors of alkali-metal ensembles, for example atomic spin waves, enables quantum memory, and is required for synchronising single-photon sources and long-range quantum cryptographic networks.

For example, in alkali metal atoms, the Rydberg state corresponds to an excitation of the outer shell electron to a state with high principle quantum number n. In such states, the effective dipoles are enlarged by a factor of n² compared to ground-state atoms. Interactions between individual atoms arise, due to overlapping wave functions, and allow controlled entanglement of the atomic ensembles. Such systems can induce strong nonlinearity even at the single photon level. Absorbing a photon into a Rydberg state causes the energy levels of all the atoms within the ensemble to shift, preventing the absorption of another photon, i.e. the system becomes transparent. This behaviour is known as a Rydberg blockade and it enables various quantum logic gates or switches, by, for example, allowing a system to be transparent to a single photon but absorbing to a photon pair.

As another example, the energy level structure of alkali metal atoms in Rubidium provides the basis for almost-degenerate two-photon excitation near 780 nm. The resulting off-resonant enhancement can boost nonlinear optical effects such as four-wave mixing. This can yield squeezed states with reduced amplitude or phase uncertainty, giving rise to a quantum enhancement of measurement precision in interferometers (which may be used in inertial sensors and space-based gravity wave detectors), quantum limited amplifiers and quantum delay lines.

To enable interactions such as these, a relatively high alkali metal vapor density is required to provide a high enough optical depth (particularly as, for some applications, the light levels may be low and the interaction may be weak) in order to increase the likelihood of successful interactions.

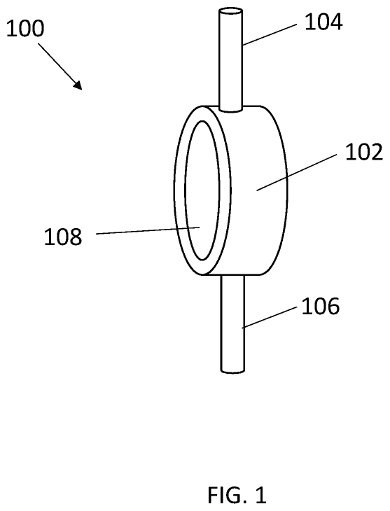

FIG. 1 shows an alkali metal vapor enclosure 100 having a main body 102, which in this example is cylindrical, and two filing stems 104, 106 in communication with the main body 102. In other examples, the enclosure could have a different shape.

The main body 102 of the enclosure 100 may be formed at least in part, of glass (for example, Pyrex™), quartz, plastic, or any suitable material. At least part of the main body 102 is transmissive to light as set out below. In some examples, the enclosure 100 has been evacuated to produce a vacuum inside the enclosure 100 and then, in some examples, alkali metal atoms have been introduced into the enclosure 100. The alkali metal atoms may be held in the enclosure 100 in a vapor form or they may be condensed/adsorbed on an inner surface of the enclosure 100, with the population in each state depending on their temperature. Heating the enclosure 100 can cause desorption of the atoms from the walls of the container such that the vapor density increases. The alkali metal atoms may be atoms of any alkali metal, for example, Rubidium, Caesium, Sodium or Potassium.

For at least some known alkali metal vapor enclosures, heating the enclosure to a sufficient temperature to cause desorption of the atoms can take 10 minutes or longer as the solid bulk of the walls is heated. ‘Light induced atomic desorption’ can also be used to increase vapor density in alkali metal vapor enclosure, but this technique can still take tens of seconds to significantly increase the vapor density.

In some examples, the main body 102 of the enclosure 100 is transmissive to light having a wavelength in a particular range, for example visible light, UV light or infra-red light. It will be clear therefore that, as used herein, the term light is not restricted to the visible part of the electromagnetic spectrum. In the example shown in FIG. 1, the main body 102 of the enclosure 100 includes a transmissive portion 108. In other examples, the main body 102 of the enclosure 100 may include two or more transmissive portions to enable light to pass into enclosure 100.

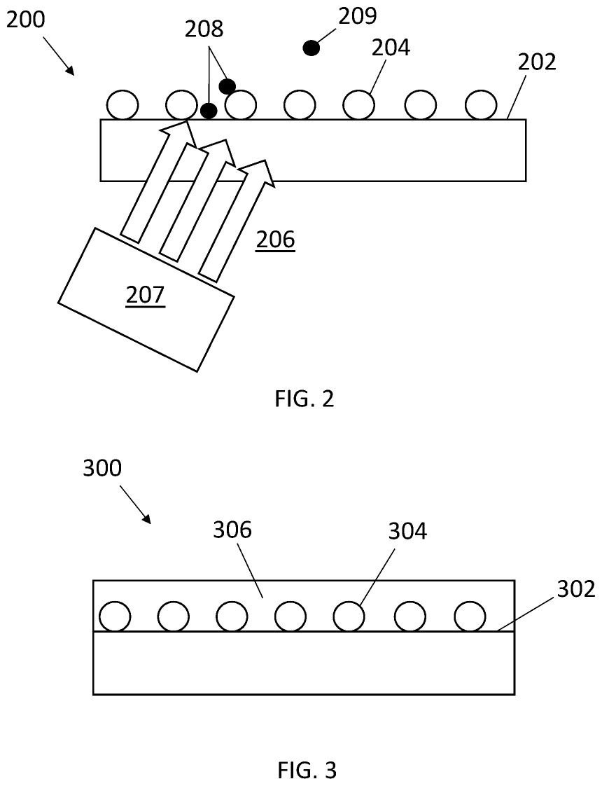

FIG. 2 shows a wall 200 of the enclosure 100 of FIG. 1. The wall has a surface 202 which is an internal surface of the enclosure 100. The surface 202 is coated with a coating layer which comprises nanoparticles 204. In some examples, the entire internal surface of the enclosure 100 may be coated with the coating layer. In other examples, one or more portions of the entire internal surface of the enclosure may be coated with the coating layer. In some examples, the coating layer may be a monolayer thin coating (thickness, for example, <80 nm). However, in some embodiments, other types of nanostructures could be used such as a nanopatterned surface or nanotubes/nanowires. Such nanostructures may have at least one dimension of between 1 and 100 nm and an enhanced optical extinction that can be excited by illumination of the nanostructures with light that has a suitable frequency. For example, the nanostructures may comprises nanoparticles formed of metal (for example, gold, silver, platinum, copper or combinations thereof) or semiconducting materials (i.e. quantum dots), composite materials (such as zinc oxide plus gold or platinum) or porous materials (such as porous glass and metal nanoparticles) In some examples, the nanostructures may comprise a nanopatterned surface such as a thin-film black-gold surface or a continuous metal surface including nanoscale holes. The nanoparticles may be generally spherical shaped or may have a different shape such as nanorods or core-shell type structures. The frequency at which the surface plasmon resonance occurs can be controllably selected by an appropriate choice of the geometry and/or the materials from which the nanoparticles are formed. This frequency can also be controllably selected by changing the material with which the nanostructures are capped/coated. Capping the nanostructures comprises providing a coating on an outer surface of the nanostructures, for example by coupling particular molecules to the surface of the nanostructures, either directly or via links to other molecules that are attached to the surface of the nanostructures. In the example shown here, the nanoparticles are gold nanoparticles having an average size of 5 nm and a size range of 3 to 7 nm, which are capped with octadecylamine (ODA) but, in other examples, other types of nanostructures may be used and/or the nanostructures may be capped with another suitable substance. Capping the nanostructures with molecules having antirelaxation properties, such as ODA, enables the quantum states of alkali metal vapor atoms that collide with the internal surface of the enclosure 100 to be preserved. In some examples, the nanoparticles may be capped with other suitable substances that exhibit antirelaxation properties. In the example shown in FIG. 2, the nanoparticles 204 on the internal surface 202 are deposited in a monolayer (i.e. a single layer of nanoparticles), but in some examples other arrangements of nanoparticles could be used, for example nanoparticles dispersed throughout a polymer layer.

The alkali metal atoms 208, 209 in the enclosure 100 may be in vapor form or they may adsorb on the side of the enclosure 100. If the temperature of the alkali metal atoms decreases, this leads to an increase in the number of atoms of the alkali metal vapor adsorbing onto internal surfaces of the enclosure 100 and a decrease in the density of the alkali metal vapor. In the example shown in FIG. 2, alkali metal atoms 208 have adsorbed onto the surface 202, whereas atom 209 is in vapor form. If the temperature of the alkali metal atoms increases, this leads to an increase in the desorption of alkali metal atoms from the surface 202 and therefore an increase in the density of the alkali metal vapor.

In use of the enclosure 100, illumination of the nanoparticles 204 with light 206 from a first light source 207 at a certain frequency (or frequencies) excites an enhanced optical extinction in the nanoparticles. Enhanced optical extinction refers to phenomena whereby energy is transferred from incident light to the nanoparticles. It results in light being absorbed by the nanoparticles or scattered away from its initial direction of propagation. For example, optical extinction may be enhanced due to a resonant absorption process, such as a surface plasmon resonance, interband transitions or intraband transitions in the nanostructures. In some examples, the nanostructures may have an enhanced optical extinction due to scattering processes. Such an enhanced optical extinction mechanism causes energy to be transferred from a light source to the nanostructure (e.g. by increasing in the temperature of the electrons in the nanostructure), which causes the nanostructure to heat up.

For example, if the nanoparticles are illuminated with light having a frequency at or close to an SPR frequency of the nanoparticles, this causes coherent oscillations of the electron density of the nanoparticles (known as a surface plasmon resonance or SPR), the energy from which is released as heat from the nanoparticles 204. The first light source 207 may be, for example, a laser, sunlight, a lamp or a light emitting diode. Light may be electromagnetic radiation of any frequency suitable to excite a surface plasmon resonance (or other enhanced optical extinction mechanism) in the nanoparticles and may be, for example, visible light, infra-red light or UV light. Therefore illumination of the inner surface 202 of the wall 200 with light at an SPR frequency causes local heating around the nanoparticles 204. The SPR frequency of the nanoparticles can vary depending on characteristics of the nanoparticles and their immediate surroundings, for example, size, shape, what they are made of and coating materials. There may be a range of frequencies of light that can excite a surface plasmon resonance in the nanoparticles sufficiently to cause heating of the nanoparticle via this mechanism. For example, for a coating of gold nanoparticles with sizes of 3 to 7 nm and capped with ODA, a suitable wavelength of light to cause heating of the nanoparticles by excitation of an SPR would be between 500 and 580 nm.

The wavelength/frequency of light suitable to excite an enhanced optical extinction mechanism such as a surface plasmon resonance, intraband transitions, or interband transitions, other resonant absorption, or scattering properties of a particular nanostructure coating may be determined using UV-Vis spectroscopy.

As nanostructures such as the nanoparticles 204 are small in size, their thermal response is relatively fast (when compared with heating up larger objects such as the entire enclosure 100). This leads to a faster desorption rate of the alkali metal atoms from the inner surfaces 202 of the enclosure 100 than in previously used techniques which therefore produces a faster increase in the density of the alkali metal vapor, enabling greater control of the vapor density. Nanoparticles or other nanostructures also lose heat quickly due to their small size, meaning that after turning off illumination of the nanoparticles at the SPR frequency, they quickly lose heat. This means that the alkali metal vapor density in an enclosure can be quickly returned to a state with lower vapor density if required (for example, within tens of milliseconds in centimetre-sized enclosures, or faster in micrometer-sized enclosures).

The alkali metal vapor density can therefore be increased by turning on the illumination source 206 and decreased by turning off or blocking the illumination source 206. In this way, providing a nanostructure coating on the inner surfaces 202 of an alkali metal vapor enclosure 100 enables the density of the alkali metal vapor to be controlled, with fast response times, by illumination of the inner surfaces 202 with light having a suitable SPR frequency.

The alkali metal vapor enclosure 100 of FIG. 1 may therefore enable control of the vapor density with a faster response time and lower power consumption (as raising the temperature of the entire enclosure 100 is not required) than for some previous alkali metal vapor enclosures.

In use of the enclosure 100, the enclosure 100 may also be illuminated with light from one or more second light sources, which are to interact with or interrogate the alkali metal vapor, in addition to the first light source 207 having a frequency to excite an enhanced optical extinction in the nanosturctures. For example, the second light source may address atomic absorption lines of the alkali metal vapor. In some examples, the one or more second light sources may pass into the enclosure 100 via transmissive portion 108. In some examples, the one or more second light sources may pass into the enclosure via a separate transmissive portion.

FIG. 3 shows another example of a wall 300 of an alkali metal vapor container such as the enclosure 100 shown in FIG. 1. The wall 300 has an inner surface 302 which is coated with nanoparticles 304 as explained above in relation to FIG. 2. The coating of FIG. 3 may be, for example, a thicker coating than the coating shown in FIG. 2 (thickness, for example, several tens of micrometers). In the example shown in FIG. 3, the coating also comprises a layer of polydimethylsiloxane (PDMS) 306, which is deposited over the nanoparticle layer. In some examples, the PDMS layer may have a thickness of between a single monolayer and 10 micrometers, depending on the deposition technique and the concentration of PDMS in the solvent. The coating may not be entirely uniform as growth can follow any of the classic growth modes, including: by layer, by island and by Stranski-Krastanov modes. In some examples, the PDMS layer 306 can be up to 100 micrometers, with surface roughness of 20 to 50 nm. In some examples, other types of antirelaxation coatings could be applied to the internal surface.

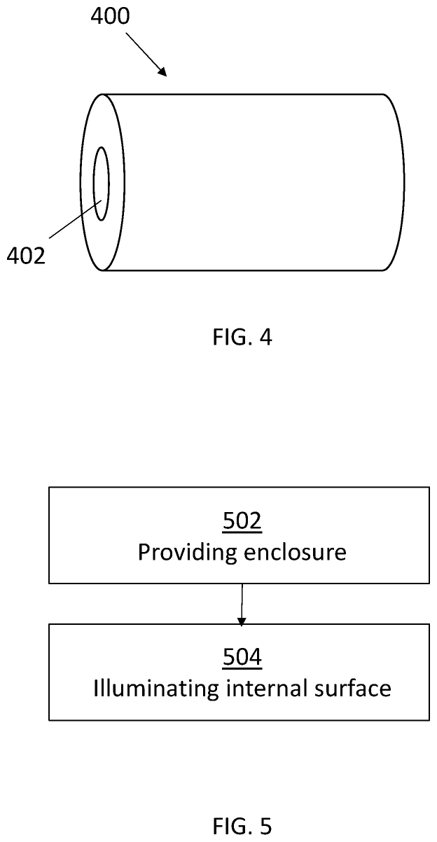

FIG. 4 shows another example of an alkali metal vapor enclosure 400. In this case the enclosure 400 is a hollow-core optical fiber which may be made of glass, for example, and which is sealed at each end with a transparent substance, (e.g. fused glass or a spliced connection to a solid optical fiber). The hollow core optical fiber has an inner surface 402 which comprises nanostructures, as has already been described above in relation to FIGS. 2 and 3. The coating shown in FIG. 2 is advantageous when used in hollow core optical fibers as it enables the transmission properties of the optical fiber to be preserved. In some examples an entire inner surface of the alkali metal vapor enclosure 400 comprises nanostructures. In other examples only part of the inner surface of the alkali metal vapor enclosure 400 comprises nanoparticles. The inner surface of the hollow core optical fiber may be coated by, for example providing a solution of nanoparticles at one end of the fiber which will then be transported along the length of the fiber by capillary action.

In use of the enclosure 400, in some examples, at least part of the optical fibre may be illuminated by light from a first light source, having a frequency suitable to excite an enhanced optical extinction mechanism. In some examples, where the walls of the optical fibre are transmissive to the light from the first light source, light from the first light source may be directed onto the outer walls of the optical fiber at a suitable angle of incidence so as to be transmitted to the internal surface. In some examples, the light from the first light source may be directed into one end of the optical fiber and propagated within the optical fibre in order to illuminate the internal surface of the enclosure 400 and excite an optical extinction mechanism in the nanostructures. In some examples, light from a second light source, having a frequency suitable to interrogate/interact with the alkali metal vapor atoms may also be propagated within the optical fibre. In some examples, the light from the first light source and the light from the second light source may propagate in the optical fiber simultaneously, for example by using a dichroic mirror. In some examples, the light from the first light source and the light from the second light source may be sent along different propagation modes in the fiber. For example, the optical path of the light from the first light source may be arranged such that the light from the first light source has a portion that propagates close to the walls of the optical fiber and the optical path of the light from the second light source may be arranged such that the light from the second light source propagates along the centre of the fibre.

In some examples, the enclosure may be any kind of enclosure suitable for holding an alkali metal vapor under near vacuum conditions (for example at 10⁻⁸ Torr, although the vacuum level will vary, depending on what proportion of the alkali metal is in vapor form). In some examples, the enclosure may be a miniaturized vapor cell, which may comprise two walls, spaced from each other by micrometer or nanometer dimensions (for example, by less than 50 micrometers). Such miniaturized vapor cells may be useful for applications such as in laser frequency stabilization, where light scattered from atomic vapor is measured across hyper-fine atomic level transitions and is fed back to the laser diode controller, chip-scale atomic clocks and magentometers, and miniaturized photonic sensors, for example for lab-on-a-chip devices. In some examples, the enclosure may be a container such as those used in cold-atom experiments such as for atom traps.

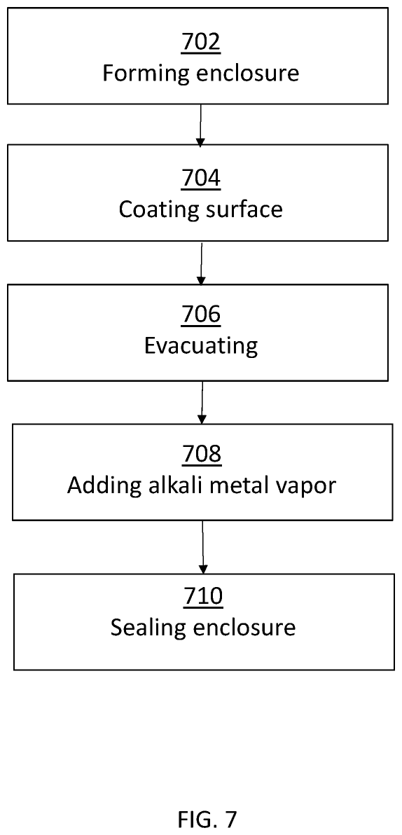

FIG. 5 shows a method of controlling alkali metal vapor density in an alkali metal vapor enclosure. The alkali metal vapor enclosure may be as described above in relation to FIGS. 1 to 4. The alkali metal vapor enclosure may be formed as described below in relation to FIG. 7.

At step 502 of the method of FIG. 5, an alkali metal vapor enclosure is provided, comprising an internal surface having a coating comprising nanostructures, for example, nanoparticles; and a transmissive portion to enable the internal surface to be illuminated; wherein the enclosure contains atoms of an alkali metal in a vapor state and/or adsorbed onto the internal surface.

Step 504 comprises illuminating the internal surface via the transmissive portion with light from a first light source, having a frequency/wavelength to excite an enhanced optical extinction mechanism, for example a surface plasmon resonance, in the nanostructures, to cause an increase in the density of the alkali metal vapor. For example, for an enclosure having a coating of gold nanoparticles with sizes of 3 to 7 nm and capped with ODA, step 504 may comprise illuminating the internal surface with light having a frequency (wavelength) of between 600 THz (500 nm) and 517 THz (580 nm), to address the SPR or with light having a frequency above 600 THz (below 500 nm) to address the interband transitions.

Therefore, using the method of FIG. 5, increases and decreases in density of the alkali metal vapor can be controlled by controlling illumination of the nanostructures on the inner surface of the enclosure.

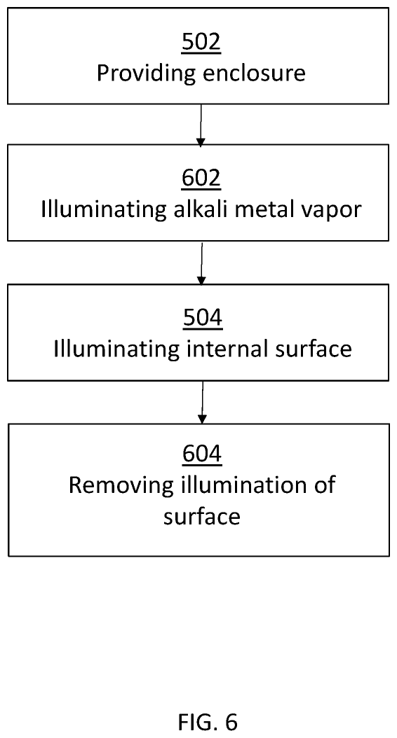

FIG. 6 shows a method of producing an alkali metal vapor enclosure such as the alkali metal vapor enclosures shown in FIGS. 1 to 4.

FIG. 6 shows another example of a method of controlling alkali metal vapor density. The method of FIG. 6 includes steps 502 and 504 as already described above in relation to FIG. 5. However, the method of FIG. 6 also includes step 602 which comprises illuminating the alkali metal vapor with light from a second light source, having a second frequency, which may be different from the nanostructure excitation frequency. That is, at step 602 the enclosure is illuminated with light from the second light source (for example, a laser or light emitting diode), through a transmissive portion, which may be the same or different from the transmissive portion through which light of the nanostructure excitation frequency is transmitted, the second light source having a frequency that may be different from the surface plasmon resonance frequency, wherein the second light source is chosen to provide light that can interact with the alkali metal atoms in the alkali metal vapor. In some examples, at step 602, the alkali metal vapor is illuminated with two or more beams of light from second light sources, which may intersect in the enclosure, in addition to the light from the first light source, having a frequency to excite an SPR (or other resonances) in the nanostructures. In some examples, the alkali metal vapor may be illuminated by the second light source(s) at the same time that the internal surface of the enclosure is illuminated with light from the first light source, i.e. light having a frequency to excite a resonance or transition in the nanostructures.

In some examples, step 602 may comprise illuminating the alkali metal vapor 209 with light from a second light source, whose frequency addresses atomic absorption lines. These frequencies may be different from the frequencies that address nanostructure resonances. Examples of absorption lines are the D₁ and D₂ lines of the alkali metals, which in the case of Rb metal are 377 THz (795 nm wavelength) and 384.4 THz (780 nm wavelength) respectively. In this step the enclosure is illuminated through a transmissive portion, which may be the same or different from the transmissive portion through which light of the nanostructure excitation frequency is transmitted, with a second light source separate from the first light source (for example, a laser or light emitting diode), wherein the second light source is to illuminate and interact with/interrogate the alkali metal vapor. In some examples, at step 602, the alkali metal vapor is illuminated with two, six or more beams of light, which may intersect in the enclosre that address the alkali metal vapor atomic absorption lines, in addition to the light having a frequency to excite an SPR (or other resonances) in the nanostructures.

Once the alkali metal vapor has been illuminated, the method proceeds to step 504. In some examples, steps 602 and 504 can be applied simultaneously.

At step 604, the method may comprise removing the light from the first light source illuminating the internal surface, (e.g. by turning off, redirecting or blocking the light) to cause a rapid decrease in the density of the alkali metal vapor, by removing the source of the nanostructure excitation. This may be particularly useful for atomic trapping applications for fast removal of the “hot” atomic vapor around the cloud of “cold” atoms, trapped in the intersection of six cooling beams. In the case of a hollow core optical fibre enclosure such as that shown in FIG. 4, steps 504 and 604 can together provide a method for fast, sub-millisecond switching of the optical density along the fibre core.

Therefore, using the method of FIG. 6, increases and decreases in density of the alkali metal vapor can be controlled by controlling illumination of the nanoparticles on the inner surface of the enclosure.

FIG. 7 shows a method of producing an alkali metal vapor enclosure such as the alkali metal vapor enclosures shown in FIGS. 1 to 4.

Step 702 comprises forming an enclosure having a transmissive portion. The enclosure may be formed, for example from glass. Step 704 comprises coating an internal surface of the enclosure with nanostructures, for example nanoparticles. This step may be performed, for example using the method described below, or in some examples the internal surface may be coated with nanostructures by for example, depositing nanoparticles, or other nanostructures on a piece of glass using electron beam lithography, and then forming the piece of glass into a wall of an alkali metal vapor enclosure using glue or glass melting methods. In other examples other nanodeposition techniques may be used. In some examples, an antirelaxation coating may be applied to the internal surface, for example an antirelaxation coating layer may be applied on top of the nanostructures. Step 706 comprises evacuating air from the enclosure to form a vacuum inside the enclosure. Step 708 comprises introducing an alkali metal vapor into the enclosure, and step 710 comprises sealing the enclosure.

In some examples, an enclosure such as that described in relation to FIGS. 1 to 6 may be produced using the following method.

### Example Method of Producing Alkali Metal Vapor Enclosure

In the example method, the main body was formed with a 12.7 mm outer diameter and a wall thickness of 1.6 mm. The length of the enclosure is 5 mm. The two filling stems 104, 106 have an outer diameter of 3 mm and wall thickness of 0.6 mm.

To produce the nanoparticles, a solution of N(C8H17)4Br (365 mg, 0.65 mmol) in toluene (25 mL) was added dropwise to a vigorously stirred orange solution of HAuCl4.3H2O (112 mg, 0.28 mmol) in deionised (DI) water (25 mL) at room temperature. Both phases were strongly coloured (orange/red for the organic phase and orange for the aqueous phase) and when the aqueous phase became colourless, octadecylamine (842 mg, 3.12 mmol) was added as a solution in toluene (25 mL). The aqueous phase became milky and a solution of NaBH4 (165 mg, 4.36 mmol) in deionised water (25 mL) was added to the stirred mixture. The organic phase became brown/black then quickly turned deep purple as the aqueous layer turned colorless. The reaction was stirred for a minimum of 12 h then the reaction layers were separated. The organic phase was concentrated under vacuum to a volume of 5 mL. The nano-particles were precipitated by adding absolute EtOH (350 mL) at room temperature. The mixture was then cooled at −60° C. and kept at −80° C. for 24 h. When returned to room temperature, the supernatant EtOH was decanted and the dark purple precipitate was filtered on a 0.45 μm cellulose film, washed twice with EtOH and dried to afford 137 mg of dry product.

The inner surfaces of the enclosure were coated by the following procedure. The enclosure was first rinsed with DI water, blow-dried with dry N2 and baked at 80° C. in a furnace for 3 days. In some examples, the enclosure was then functionalized with 1 M NaOH for 1 hour, followed by rinsing with DI water for another hour. The enclosure was then blow dried with N2. The main body of the enclosure and the first 4 cm of each stem were filled with a chloroform solution of the Au NPs (6 mg ODA-capped Au/6 ml chloroform) for up to 10 min. The enclosure was dried up again in a furnace at 80° C. for a day. The last two steps of the procedure were repeated.

In some examples, such as the example shown in FIG. 3, Poly(dimethylsiloxane), bis(3-aminopropyl) terminated (PDMS) was diluted into a 0.5% diethyl ether solution by mixing for 1 hour in a magnetic stirrer and then the enclosure was filled with the PDMS solution. The enclosure was then dried out by placing initially onto a hot plate at 80° C. for half an hour and then into a furnace at the same temperature for a day.

After the coating had been applied, the enclosure was baked at 120° C. and 10⁻⁸ Torr for approximately 12 hours and then the alkali metal vapor was introduced into the enclosure via the filling stems. After the alkali metal vapor was introduced into the enclosure, the filling stems were sealed at 4 cm from the main body of the enclosure.

1. An alkali metal vapor enclosure comprising:
an internal surface comprising nanostructures;
a transmissive portion to enable the internal surface to be illuminated;
wherein the enclosure contains atoms of an alkali metal which are in a vapor state and/or adsorbed onto the internal surface; and
wherein illumination of the internal surface via the transmissive portion with light having a frequency to cause a temperature rise in the nanostructures by exciting an enhanced optical extinction mechanism in the nanostructures, causes an increase in a density of the alkali metal vapor.

2. The alkali metal vapor enclosure according to claim 1, wherein the enhanced optical extinction mechanism is a resonant absorption or scattering mechanism in the nanostructures.

3. The alkali metal vapor enclosure according to claim 2, wherein the resonant absorption or scattering mechanism is a surface plasmon resonance, an interband transition, or an intraband transition in the nanostructures.

4. The alkali metal vapor enclosure according to claim 1, wherein the nanostructures are at least partly covered by a polymer layer.

5. The alkali metal vapor enclosure according to claim 1, further comprising an antirelaxation coating on the internal surface.

6. The alkali metal vapor enclosure according to claim 4 wherein the polymer layer comprises an antirelaxation coating of polydimethylsiloxane (PDMS).

7. The alkali metal vapor enclosure according to claim 1, wherein the nanostructures comprise metal nanoparticles.

8. (canceled)

9. The alkali metal vapor enclosure according to claim 7 wherein the metal nanoparticles comprise gold nanoparticles.

10. The alkali metal vapor enclosure according to claim 1 wherein the enclosure is a glass or quartz vacuum cell.

11. The alkali metal vapor enclosure according to claim 1 wherein the enclosure is a hollow-core optical fiber.

12. The alkali metal vapor enclosure according to claim 1 wherein the nanostructures are capped with an antirelaxation material.

13. The alkali metal vapor enclosure according to claim 12, wherein the nanostructures are capped with octadecylamine (ODA).

14. The alkali metal vapor enclosure according to claim 1 wherein the enhanced optical extinction mechanism is excitable by light in the visible range of the electromagnetic spectrum.

15. A system comprising an alkali metal vapor enclosure device according to claim 1; and
a first light source arranged to illuminate the internal surface via the transmissive portion with light having a frequency to cause a temperature rise in the nanostructures by exciting an enhanced optical extinction mechanism in the nanostructures.

16. A method comprising:
illuminating an internal surface of an alkali metal vapor enclosure, wherein the internal surface comprises plasmonic nanoparticles, with light from a first light source, having a frequency to cause a temperature rise in the nanostructures by exciting an enhanced optical extinction mechanism in the nanostructures, to cause an increase in the density of the alkali metal vapor.

17. The method according to claim 16 further comprising illuminating the alkali metal vapor with light from a second light source, wherein the light from the second light source is to interact with the alkali metal vapor.

18. The method according to claim 16 further comprising ceasing illumination of the internal surface with the first light source to cause a decrease in the density of the alkali metal vapor.

19. A method of producing an alkali metal vapor enclosure comprising:
forming an enclosure having a transmissive portion;
coating an internal surface of the enclosure with nanoparticles;
evacuating air from the enclosure;
introducing an alkali metal vapor into the enclosure;
sealing the enclosure.

20. A u se of an alkali metal vapour enclosure according to of claim 1 in an atomic clock, a magnetometer, an atom trap, or a laser frequency stabilizer.

21. An atomic clock, a magnetometer, a photonic sensor, a quantum switch, a quantum logic gate, a quantum memory based on quantum logic gates, an atom trap, a quantum interferometer, a laser frequency stabilizer, quantum limited amplifiers or a quantum delay line comprising an alkali metal vapor enclosure according to claim 1.
